(19) United States
(12) Patent Application Publication
(10) Pub. No.: US 2026/0190804 A1
(43) Pub. Date: Jul. 2, 2026

(54) LIGHT EMITTING DISPLAY APPARATUS

(71) Applicant: LG Display Co., Ltd., Seoul (KR)

(72) Inventor: Nayoung LEE, Paju-si (KR)

(73) Assignee: LG Display Co., Ltd., Seoul (KR)

(21) Appl. No.: 19/215,722

(22) Filed: May 22, 2025

(30) Foreign Application Priority Data
Dec. 31, 2024 (KR) 10-2024-0202270

(51) Int. Cl. H10K 59/80; H10K 59/35

(52) U.S. Cl. CPC H10K 59/879; H10K 59/353; H10K 59/351

(57) ABSTRACT

A light emitting display apparatus may include a substrate, a plurality of sub-pixels, a light extraction pattern disposed at each of the plurality of sub-pixels, and a light emitting device layer disposed on the light extraction pattern. The light extraction pattern may include a plurality of concave portions and a convex portion around the plurality of concave portions, each of the plurality of concave portions may include a bottom portion and an inclined portion surrounding the bottom portion, and a width of the bottom portion of the light extraction pattern disposed in each of the plurality of sub-pixels may be different from each other.

### CROSS-REFERENCE TO RELATED APPLICATION

This application claims the benefit of and priority to Korean Patent Application No. 10-2024-0202270 filed on Dec. 31, 2024, the entire contents of which are incorporated herein by reference for all purposes as if fully set forth herein.

### BACKGROUND

### 1. Technical Field

The present disclosure relates to a light emitting display apparatus.

### 2. Description of Related Art

A light emitting display apparatus is attracting attention as next-generation flat panel displays because it has a high response speed, low power consumption, and does not require a separate light source, unlike liquid crystal displays.

The light emitting display apparatus displays an image through the light emission of a light emitting device, which includes a light emitting layer interposed between two electrodes. In this case, light generated according to the light emission of the light emitting device is emitted to the outside through an electrode, a substrate, or the like.

However, the light emitting display apparatus experiences a reduction in light extraction efficiency because some of the light emitted from the light-emitting layer fails to be emitted outward due to total internal reflection at the interface between the light-emitting layer and the electrode and/or at the interface between the substrate and the air layer.

The description of related art should not be considered prior art merely because it is mentioned in or associated with this section. The description of related art includes information that describes one or more aspects of the subject technology, and the description in this section does not limit the scope of the invention.

### SUMMARY

An aspect of the present disclosure is directed to providing a light emitting display apparatus capable of improving light extraction efficiency of light emitted from a light emitting device.

An aspect of the present disclosure is directed to providing a light emitting display apparatus capable of improving a visual perception characteristic of black images according to a decrease in diffusion reflectance while improving the light extraction efficiency of light emitted from a light emitting device.

Additional advantages and features of the disclosure will be set forth in part in the description which follows and in part will become apparent to those having ordinary skill in the art upon examination of the following or may be learned from practice of the disclosure. The aspects and other advantages of the disclosure may be realized and attained by the structure particularly pointed out in the written description as well as the appended drawings.

To achieve these and other advantages and aspects of the present disclosure, as embodied and broadly described herein, in one or more aspects, a light emitting display apparatus may comprise a substrate, a plurality of sub-pixels, a light extraction pattern disposed on each of the plurality of sub-pixels, and a light emitting device layer disposed on the light extraction pattern. The light extraction pattern may include a plurality of concave portions and a convex portion around the plurality of concave portions. Each of the plurality of concave portions may include a bottom portion and an inclined portion surrounding the bottom portion. A width of the bottom portion of the light extraction pattern disposed in each of the plurality of sub-pixels may be different from each other.

Details of other example embodiments will be included in the detailed description of the disclosure and the accompanying drawings.

According to one or more embodiments of the present disclosure, the light emitting display apparatus may improve the light extraction efficiency of the light emitted from the light emitting device, and a visual perception characteristic of black images may be enhanced due to the reduction in external light reflection.

According to one or more embodiments of the present disclosure, the light emitting display apparatus improves light extraction efficiency and a visual perception characteristic of black images, and thus, there is an effect of reducing power consumption and driving low power according to the improvement of a lifetime.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the following claims. Nothing in this section should be taken as a limitation on those claims. Further aspects and advantages are discussed below in conjunction with aspects of the disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure.

FIG. 1 is a diagram schematically illustrating a light emitting display apparatus according to an embodiment of the present disclosure.

FIG. 2 is an equivalent circuit diagram illustrating the first pixel shown in FIG. 1.

FIG. 3 is a cross-sectional view illustrating a structure of a pixel according to an embodiment of the present disclosure.

FIG. 4 is an enlarged view of part A shown in FIG. 3.

FIG. 5 is a plan view illustrating a light extraction pattern shown in FIG. 3.

FIG. 6 is a cross-sectional view illustrating a cross-sectional structure of a light extraction pattern in each pixel area according to an embodiment of the present disclosure.

FIGS. 7A to 7D are diagrams illustrating light extraction efficiency of a light emitting display apparatus according to a width of a bottom portion according to an embodiment of the present disclosure.

FIGS. 8A to 8D are diagrams illustrating light extraction efficiency of a light emitting display apparatus according to a height of a light extraction pattern according to an embodiment of the present disclosure.

FIG. 9 is a diagram illustrating an image of a light extraction pattern according to an embodiment of the present disclosure.

FIG. 10 is a diagram illustrating a 3D image of a light extraction pattern according to an embodiment of the present disclosure.

FIGS. 11A and 11B are diagrams showing a visual perception of black images according to an experimental example and an embodiment of the present disclosure.

FIG. 12 is a diagram illustrating diffuse reflection according to the width of the bottom portion of the light extraction pattern according to an embodiment of the present disclosure.

FIG. 13 is a diagram illustrating the intensity of light according to the wavelength range in the experimental example and the embodiment of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction of thereof may be exaggerated for clarity, illustration, and convenience.

### DETAILED DESCRIPTION OF THE DISCLOSURE

Advantages and features of the present disclosure, and implementation methods thereof will be clarified through following embodiments described with reference to the accompanying drawings. The present disclosure can, however, be embodied in different forms and should not be construed as limited to the embodiments set forth herein. Rather, these embodiments are provided so that this disclosure will be thorough and complete, and will fully convey the scope of the present disclosure to those skilled in the art.

A shape, a size, a ratio, an angle, and a number disclosed in the drawings for describing embodiments of the present disclosure are merely an example, and thus, the present disclosure is not limited to the illustrated details. Like reference numerals refer to like elements throughout. In the following description, when the detailed description of the relevant known function or configuration is determined to unnecessarily obscure the important point of the present disclosure, the detailed description will be omitted.

When the term “comprise,” “have,” “include,” “contain,” “constitute,” “made of,” “formed of,” “composed of,” or the like is used with respect to one or more elements (e.g., layers, films, components, electrodes, structures, transistors, sections, members, parts, regions, areas, portions, steps, operations, and/or the like), one or more other elements may be added unless a term such as “only” or the like is used. The terms in a singular form may include plural forms unless noted to the contrary. For example, an element may be one or more elements. An element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

In construing an element, the element is construed as including an error or tolerance range although there is no explicit description of such an error or tolerance range.

In describing a position relationship, for example, when a position relation between two parts is described as, for example, “on,” “over,” “under,” and “next,” one or more other parts can be disposed between the two parts unless a more limiting term, such as “just” or “direct(ly)” is used.

In describing a time relationship, for example, when the temporal order is described as, for example, “after,” “subsequent,” “next,” and “before,” a case that is not continuous can be included unless a more limiting term, such as “just,” “immediate(ly),” or “direct(ly)” is used.

It will be understood that, although the terms “first,” “second,” and the like can be used herein to describe various elements, these elements should not be limited by these terms. These terms are only used to distinguish one element from another and may not define any order. For example, a first element could be termed a second element, and, similarly, a second element could be termed a first element, without departing from the scope of the present disclosure.

The term “at least one” should be understood as including any and all combinations of one or more of the associated listed items. For example, the meaning of “at least one of a first item, a second item, and a third item” denotes the combination of all items proposed from two or more of the first item, the second item, and the third item as well as the first item, the second item, or the third item. Also, the term “can” used herein includes all meanings and definitions of the word “may.”

Features of various embodiments of the present disclosure can be partially or overall coupled to or combined with each other, and can be variously inter-operated with each other and driven technically as those skilled in the art can sufficiently understand. The embodiments of the present disclosure can be carried out independently from each other, or can be carried out together in co-dependent relationship.

Hereinafter, embodiments of the present disclosure will be described in detail with reference to the accompanying drawings. For convenience of description, a scale of each of elements shown in the accompanying drawings differs from a real scale, and thus, is not limited to a scale shown in the drawings.

FIG. 1 is a diagram schematically illustrating a light emitting display apparatus according to an embodiment of the present disclosure.

Referring to FIG. 1, a light emitting display apparatus according to the present disclosure may include a display panel 10, a control circuit 30, a data driving circuit 50, and a gate driving circuit 70.

The display panel 10 may include a plurality of gate lines GL and a plurality of data lines DL provided on a substrate, and a plurality of sub-pixels 12a, 12b, 12c, and 12d formed in a pixel area defined by the plurality of gate lines GL and the plurality of data lines DL.

Each of the plurality of sub-pixels 12a, 12b, 12c, and 12d displays an image according to a gate signal supplied from the adjacent gate line GL and a data signal supplied from the adjacent data line DL. Each of the plurality of sub-pixels 12a, 12b, 12c, and 12d according to an embodiment may include a pixel circuit provided in a pixel area and a light emitting device connected to the pixel circuit.

According to an embodiment of the present disclosure, each of the plurality of unit pixels or pixels 12 may include first to fourth sub-pixels 12a, 12b, 12c, and 12d parallel to each other in the first direction X. Each of the plurality of sub-pixels 12a, 12b, 12c, and 12d may be defined as an area of a minimum unit in which actual light is emitted. For example, four sub-pixels adjacent to each other may configure one unit pixel 12 for color display.

One unit pixel 12 may include four sub-pixels 12a, 12b, 12c, and 12d arranged adjacent to each other along a length direction of the gate line GL. For example, one unit pixel 12 may include first to fourth sub-pixels 12a, 12b, 12c, and 12d. In this case, the first sub-pixel 12a may be a red sub-pixel, the second sub-pixel 12b may be a white sub-pixel, the third sub-pixel 12c may be a green sub-pixel, and the fourth sub-pixel 12d may be a blue sub-pixel.

The light emitting devices of the first to fourth pixels 12a, 12b, 12c, and 12d according to the embodiment may emit different color light.

The control circuit 30 may generate pixel data for each pixel corresponding to each of the plurality of sub-pixels 12a, 12b, 12c, and 12d based on image data input from the outside. The control circuit 30 may generate a data control signal based on the timing synchronization signal and provide the generated data control signal to the data driving circuit 50. The control circuit 30 may generate a gate control signal based on the timing synchronization signal and provide the generated gate control signal to the gate driving circuit 70.

The data driving circuit 50 may be connected to a plurality of data lines DL provided on the display panel 10. The data driving circuit 50 may receive pixel data and a data control signal for each pixel provided from the control circuit 30, and may receive a plurality of reference gamma voltages provided from the power supply circuit. The data driving circuit 50 may convert pixel-specific pixel data into pixel-specific data signals (or voltages) using a data control signal and a plurality of reference gamma voltages, and supply the converted pixel-specific data signal to the corresponding data line DL.

The gate driving circuit 70 may be connected to a plurality of gate lines GL provided on the display panel 10. The gate driving circuit 70 may generate a gate signal in a predetermined order based on the gate control signal supplied from the control circuit 30 and supply the gate signal to a corresponding gate line GL.

The gate driving circuit 70 according to an embodiment may be integrated at one or both edges of the display panel 10, depending on the manufacturing process of the thin-film transistor, and is connected to the plurality of gate lines GL in a one-to-one configuration. The gate driving circuit 70 according to another embodiment may be implemented as an integrated circuit and mounted on a substrate or flexible circuit film, where it is connected to each of the plurality of gate lines GL in a one-to-one configuration.

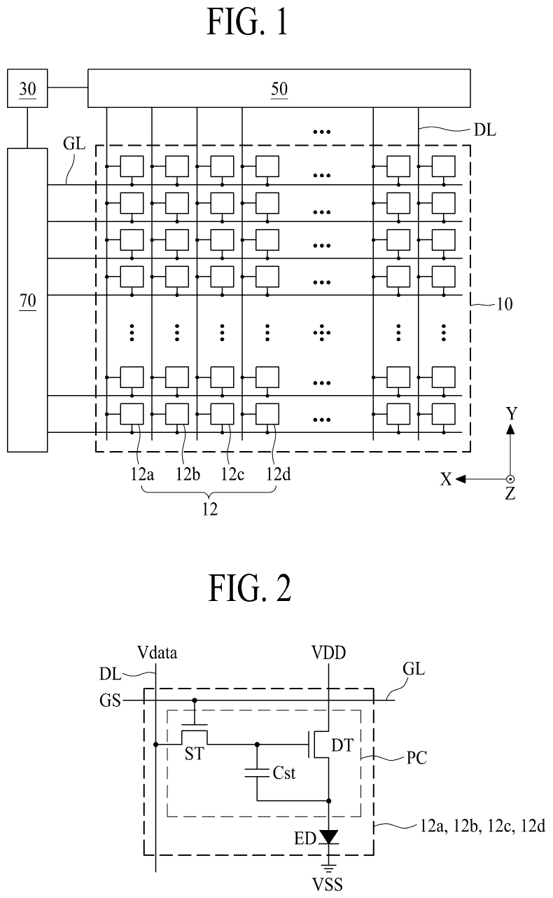

FIG. 2 is an equivalent circuit diagram illustrating the first pixel shown in FIG. 1.

Referring to FIG. 2, each of the first to fourth sub-pixels 12a, 12b, 12c, and 12d of the light emitting display apparatus according to an embodiment of the present disclosure may include a pixel circuit PC and a light emitting device ED.

The pixel circuit PC may be provided in a circuit portion in a pixel area defined by the gate line GL and the data line DL, and may be connected to the adjacent gate line GL, the data line DL, and the first driving power source VDD. The pixel circuit PC may control the light emission of the light emitting device ED according to the data signal Vdata from the data line DL in response to the gate-on signal GS from the gate line GL. For example, the pixel circuit PC may include a switching thin film transistor ST, a driving thin film transistor DT, and a capacitor Cst.

The switching thin film transistor ST may include a gate electrode connected to the gate line GL, a first source/drain electrode connected to the data line DL, and a second source/drain electrode connected to the gate electrode of the driving thin film transistor DT. The switching thin film transistor ST is turned on according to the gate-on signal GS supplied to the gate line GL, and thus, the data signal Vdata supplied to the data line DL may be supplied to the gate electrode of the driving thin film transistor DT.

The driving thin film transistor DT may include a gate electrode connected to the second source/drain electrode of the switching thin film transistor ST, a drain electrode connected to the first driving power source VDD, and a source electrode connected to the light emitting device ED. The driving thin film transistor DT is turned on according to a gate-source voltage based on the data signal Vdata supplied from the switching thin film transistor ST, and thus, a current (or data current) supplied from the first driving power source VDD to the light emitting device ED may be controlled.

The capacitor Cst is formed between the gate electrode and the source electrode of the driving thin film transistor DT, and stores a voltage corresponding to the data signal Vdata supplied to the gate electrode of the driving thin film transistor DT, and turns on the driving thin film transistor DT with the stored voltage. In this case, the voltage stored in the capacitor Cst may be maintained until a new data signal Vdata is supplied through the switching thin film transistor ST in the next frame.

The light emitting device ED is provided in an opening potion defined in the pixel area and may emit light according to the current supplied from the pixel circuit PC.

The light emitting device ED according to an example may be interposed between the first electrode (or the anode electrode) connected to the pixel circuit PC and the second electrode (or the cathode electrode) connected to the second driving power source VSS. For example, the light emitting device ED may include an organic light emitting device, a quantum dot light emitting device, or an inorganic light emitting device, or may include a micro light emitting diode device.

The first to fourth sub-pixels 12a, 12b, 12c, and 12d of the light emitting display apparatus according to the embodiment of the present disclosure display a predetermined image through light emission of the light emitting device ED according to the current corresponding to the data signal Vdata.

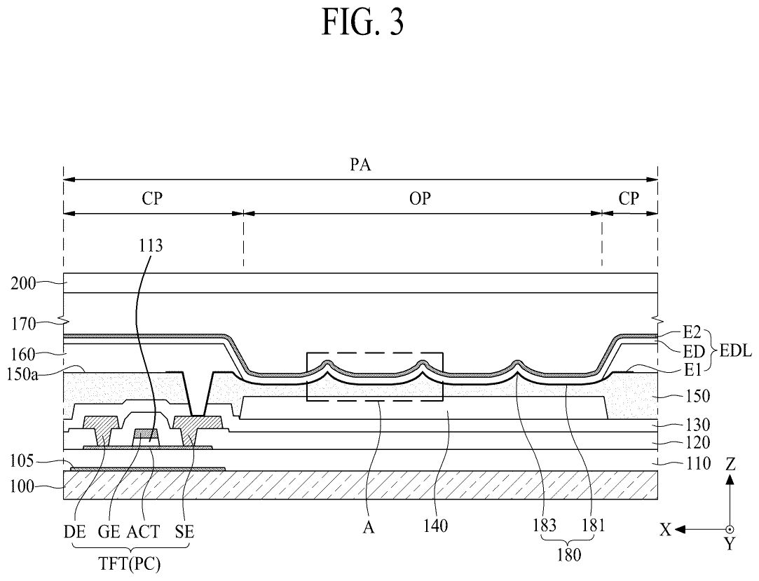

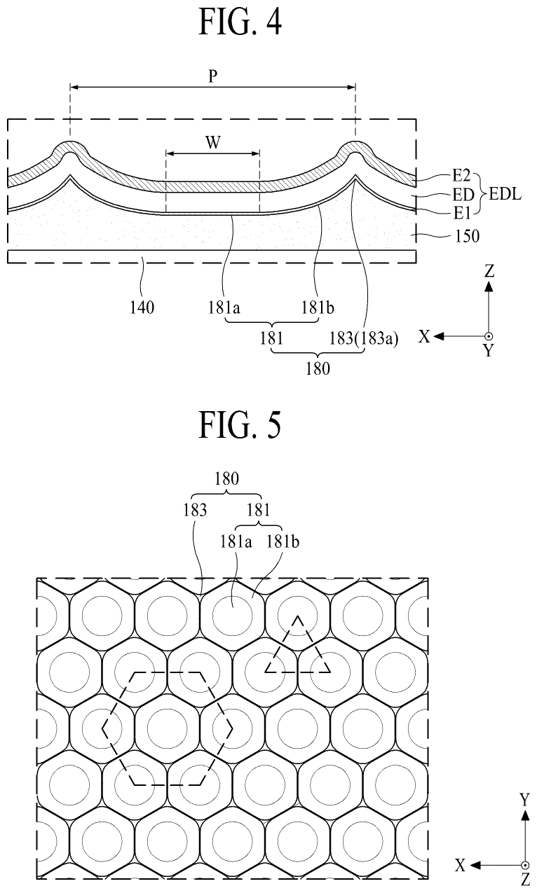

FIG. 3 is a cross-sectional view illustrating a structure of a pixel according to an embodiment of the present disclosure. FIG. 4 is an enlarged view of part A shown in FIG. 3. FIG. 5 is a plan view illustrating a light extraction pattern shown in FIG. 3.

Referring to FIGS. 3 to 5, a light emitting display apparatus (or a light emitting display panel) 10 according to an embodiment of the present disclosure may include a substrate 100, a pixel circuit PC, a wavelength conversion layer 140, an overcoating layer 150, a light extraction pattern 180, a light emitting device layer EDL, and an encapsulation portion 170.

The substrate 100 includes a thin film transistor and may be a transistor array substrate, a lower substrate, a base substrate, or a first substrate. For example, the substrate 100 may be a transparent glass substrate or a transparent plastic substrate.

The substrate 100 may include a pixel area PA having a circuit portion CP and an opening portion OP. The circuit portion CP may be defined as a transistor area defined in the pixel area PA. The opening portion OP may be defined as a light extraction area in which light generated by the light emitting device layer EDL disposed in the pixel area PA is extracted (or emitted) to the outside.

The light emitting display apparatus 10 according to an embodiment of the present disclosure may further include a light blocking layer 105.

The light blocking layer 105 may be disposed on the substrate 100. The light blocking layer 105 may be disposed on the circuit portion CP. The light blocking layer 105 may be disposed under the pixel circuit PC. The light blocking layer 105 may be configured to prevent a change in a threshold voltage Vth of a thin film transistor in the pixel circuit PC by external light incident from the outside of the display panel. For example, the light blocking layer 105 may also serve as a lower gate electrode of the transistor by being electrically connected to a source electrode of the transistor or a separate bias power source. In this case, a change in characteristics due to light and a change in threshold voltage of the transistor according to the bias voltage can be minimized or prevented.

The light emitting display apparatus 10 according to an embodiment of the present disclosure may further include a buffer layer 110.

The buffer layer 110 may be disposed on the substrate 100. The buffer layer 110 may be configured to cover the light blocking layer 105. For example, the buffer layer 110 may serve to prevent the diffusion of a material contained in the substrate 100 into the transistor during high-temperature processes in the manufacturing process of the thin film transistor. For example, the buffer layer 110 may serve to prevent external moisture or moisture from penetrating toward the light emitting device layer EDL. For example, the buffer layer 110 may be omitted based on the type and material of the substrate 100.

The pixel circuit PC may include a driving thin film transistor TFT disposed on the circuit portion CP on the substrate 100 or the buffer layer 110.

The driving thin film transistor TFT may include an active layer ACT, a gate electrode GE, a source electrode SE, and a drain electrode DE.

The active layer ACT may be disposed on the substrate 100 or the buffer layer 110. For example, the active layer ACT may include a semiconductor material based on a metal oxide such as indium-gallium-zinc-oxide (IGZO). However, the present disclosure is not limited thereto, and may include a silicon-based semiconductor material such as amorphous silicon or polycrystalline silicon. For example, the active layer ACT may be formed in a pattern shape by depositing a semiconductor material on the buffer layer 110, a heat treatment process for stabilization, and a patterning process of the semiconductor material.

The active layer ACT may include a source region, a drain region, and a channel region between the source region and the drain region. At least a portion of the active layer ACT may be covered by the first insulating layer or the gate insulating layer 113.

The first insulating layer 113 may be formed in the form of an island only on the channel region of the active layer ACT or may be formed to cover the entire front surface of the substrate 100 or the buffer layer 110 including the active layer ACT. The first insulating layer 113 may be formed of an inorganic material, but is not limited thereto and may be formed of an organic material.

The gate electrode GE may be disposed on the first insulating layer 113 to overlap a channel region of the active layer ACT. The gate electrode GE may be formed of a gate metal material. The gate electrode GE may be formed together with the gate line.

The gate electrode GE may be covered by the second insulating layer (or interlayer insulating layer) 120. The second insulating layer 120 may be formed on the first insulating layer 113 to cover the gate electrode GE. The second insulating layer 120 may be formed of an inorganic material, but is not limited thereto and may also be formed of an organic material.

The source electrode SE may be disposed on the second insulating layer 120 to be electrically connected to the source region of the active layer ACT. The source electrode SE may be electrically connected to the source region of the active layer ACT through a contact hole formed in the second insulating layer 120 overlapping the source region of the active layer ACT.

The drain electrode DE may be disposed on the second insulating layer 120 to be electrically connected to the drain region of the active layer ACT. The drain electrode DE may be electrically connected to the drain region of the active layer ACT through a contact hole formed in the second insulating layer 113 overlapping the drain region of the active layer ACT.

The source electrode SE and the drain electrode DE may be formed of a source/drain metal material. For example, the source electrode SE and the drain electrode DE may be formed of a conductive material the same as or different from that of the gate electrode GE. The source electrode SE and the drain electrode DE may be formed together with the data line DL described with reference to FIG. 1.

The pixel circuit PC may further include at least one switching thin film transistor and at least one capacitor disposed in the pixel area PA. At least one switching thin film transistor and at least one capacitor may be formed together with the driving thin film transistor TFT.

The light emitting display apparatus 10 according to an embodiment of the present disclosure may further include a passivation layer 130.

The passivation layer 130 may be configured on the second insulating layer 120. The passivation layer 130 may be configured on the pixel circuit PC. The pixel circuit PC may be covered by the passivation layer 130. The passivation layer 130 may be configured of an inorganic material or an organic material. The passivation layer 130 may be omitted.

The wavelength conversion layer 140 may be disposed on the passivation layer 130. The wavelength conversion layer 140 may be disposed between the substrate 100 and the overcoating layer 150 to overlap the opening portion OP. For example, the wavelength conversion layer 120a, 120b, and 120c may be provided between the passivation layer 130 and the overcoating layer 150 to overlap the opening portion OP.

Referring to FIGS. 1 and 3, the wavelength conversion layer 140 according to an embodiment of the present disclosure may include a color filter that transmits only a wavelength of a color set in a pixel among light emitted from the light emitting device ED of the corresponding pixels 12a, 12b, 12c, and 12c toward the substrate 100. For example, the wavelength conversion layer 140 may include a red color filter overlapping the opening portion OP of the first sub-pixel 12a, a white color filter overlapping the opening portion OP of the second sub-pixel 12b, a green color filter overlapping the opening portion OP of the third sub-pixel 12c, and a blue color filter overlapping the opening portion OP of the fourth sub-pixel 12d. According to an embodiment of the present disclosure, the first sub-pixel 12a may be a red sub-pixel, the second sub-pixel 12b may be a white sub-pixel, the third sub-pixel 12c may be a green sub-pixel, and the fourth sub-pixel 12d may be a green sub-pixel.

Referring to FIGS. 1, 3 to 5, the overcoating layer 150 may be disposed in the pixel area PA. The overcoating layer 150 may cover the pixel circuit PC or the passivation layer 130. For example, the overcoating layer 150 may be configured to planarize an upper portion of the pixel circuit PC or the passivation layer 130 and protect the pixel circuit PC. The overcoating layer 150 may be configured of an organic material. For example, the overcoating layer 150 may be formed of an organic material including acrylic resin, epoxy resin, phenolic resin, polyamide resin, or polyimide resin.

The light extraction pattern 180 may be configured in the overcoating layer 150. The light extraction pattern 180 may be formed on the upper surface 150a of the overcoating layer 150. The light extraction pattern 180 may be disposed in each of the pixel areas PA. The light extraction pattern 180 may be disposed in each of a plurality of sub-pixels 12a, 12b, 12c, and 12d. The overcoating layer 150 may include a light extraction pattern 180 disposed in each of a plurality of sub-pixels 12a, 12b, 12c, and 12d.

The light extraction pattern 180 may be disposed to overlap the opening portion OP of each of the plurality of sub-pixels 12a, 12b, 12c, and 12d. The light extraction pattern 180 is provided in the overcoating layer 150 on the opening portion OP so as to have a curved (or uneven) shape, and thus, light extraction efficiency of the pixel may be increased by changing a traveling path of the light emitted from the light emitting device layer EDL. Accordingly, the light extraction pattern 180 may also be expressed as a microlens or a light scattering pattern.

According to an embodiment of the present disclosure, the light extraction pattern 180 may include a plurality of concave portions 181 and convex portion 183.

According to an embodiment of the present disclosure, each of the plurality of sub-pixels 12a, 12b, 12c, and 12d includes a light extraction pattern 180. The plurality of concave portions 181 may be disposed on each of a plurality of sub-pixels 12a, 12b, 12c, and 12d. Each of the plurality of sub-pixels 12a, 12b, 12c, and 12d may include a plurality of concave portions 181.

Each of the plurality of concave portions 181 may be disposed in the opening portion OP of the pixel area PA. Each of the plurality of concave portions 181 may be configured to be concave from the upper surface 150a of the overcoating layer 150. Each of the plurality of concave portions 181 may be surrounded by the convex portion 181.

Each of the plurality of concave portions 181 may be disposed in parallel along the first direction X and may be disposed in a zigzag shape along the second direction Y so as to have a predetermined interval. For example, each of the plurality of concave portions 181 may be disposed in a grid shape having a predetermined interval, and the adjacent concave portions 181 may be disposed to cross each other in the second direction Y. Accordingly, the center of each of the three adjacent concave portions 181 may form a triangular shape. In addition, each of the plurality of concave portions 181 may be surrounded by six concave portions 181 disposed around it, and in this case, the center of each of the six concave portions 181 surrounding one concave portion 181 may form a hexagonal shape in plan view.

Each of the plurality of concave portions 181 may include a bottom portion 181a and an inclined portion 181b surrounding the bottom portion 181a.

The bottom portion 181a may be disposed in the center of each of the plurality of concave portions 181. The bottom portion 181a may be surrounded by the inclined portion 181b. The bottom portion 181a may be disposed at a position lower than the inclined portion 181b. The distance or height from the substrate 100 to the bottom portion 181a may be less than the distance or height from the substrate 100 to the inclined portion 181b. For example, the bottom portion 181a may be a flat portion configured in the center of each of the plurality of concave portions 181. For example, the bottom portion 181a may have a circular shape or an elliptical shape, but is not limited thereto. For example, the bottom portion 181a may be a flat portion, a flat portion, a central portion, or a lower end portion.

The inclined portion 181b may be provided on the overcoating layer 150 overlapping the opening portion OP so as to have a shape capable of maximizing external extraction efficiency of light generated from a pixel based on the effective light emitting area of the light emitting device layer EDL. The inclined portion 181b may be disposed on an edge of each of the plurality of concave portions 181. The inclined portion 181b may be disposed on the periphery of each of the plurality of concave portions 181. The inclined portion 181b may surround the bottom portion 181a. The inclined portion 181b may extend from the end of the bottom portion 181a to the upper surface 150a of the overcoating layer 150. The inclined portion 181b changes the path of light emitted from the light emitting device layer EDL toward the substrate 100, and thus, the external extraction efficiency of the light emitted from the light emitting device layer EDL may be increased.

The inclined portion 181b may be disposed between the bottom portion 181a and the convex portion 183, and thus, the inclined portion 181b may connect the bottom portion 181a and the adjacent convex portion 183. For example, the inclined portion 181b may include an inclined surface or a curved portion inclined at a first angle θ from the upper surface of the bottom portion 181a. For example, the first angle θ may range from 21° to 40°. For example, when the first angle θ is less than 21° or exceeds 40°, light extraction efficiency may be reduced. In addition, when the first angle θ is less than 21° or exceeds 40°, the diameter or width W of the bottom portion 181a cannot be maintained in the range of 59% to 92% of the interval (or pitch) P between the top portions 183a of the convex portion 183. Therefore, the first angle θ may be set in the range of 21° to 40°.

For example, the inclined portion 181b may be a light extraction portion, a light extraction surface, an inclined surface, or a curved surface portion.

The convex portion 183 may be disposed in the opening portion OP. The convex portion 183 may be connected to each other in all directions. The convex portion 183 may be connected to the adjacent concave portion 181 in all directions. The convex portion 183 may be connected to the adjacent inclined portion 181b in all directions. Accordingly, the overcoating layer 150 overlapping the opening portion OP may include a plurality of concave portions 181 formed between the convex portion 183. One concave portion 181 may be surrounded by an adjacent convex portion 183. The convex portion 183 surrounding one concave portion 181 may be provided in a hexagonal shape (or a honeycomb shape) in a plan view.

According to an embodiment of the present disclosure, the distance (or pitch) P between the top portions 183a of the convex portion 183 may be set to be the same for each of the sub-pixels 12a, 12b, 12c, and 12d within a process error range. The diameter or width W of the bottom portion 181a may be set differently for each of the sub-pixels 12a, 12b, 12c, and 12d. Depending on the diameter or width W of the bottom portion 181a, the height of the inclined portion 181b may be set differently for each sub-pixel 12a, 12b, 12c, and 12d.

According to an embodiment of the present disclosure, in each of the plurality of concave portions 181, the diameter or width (W) of the bottom portion 181a may be smaller than the interval (or pitch) (P) between the top portions 183a of the convex portion 183. For example, the diameter or width W of the bottom portion 181a may range from 59% to 92% of the interval (or pitch) P between the top portions 183a of the convex portion 183.

The external extraction efficiency of light may be increased by changing the path of the light emitted from the light emitting device layer EDL toward the substrate 100 through the inclined portion 181b. For example, when the concave portion 181 is formed in a hemispherical structure in which the bottom portion 181a is not formed, a region that does not participate in the extraction of light may occur in the center of the concave portion 181. In this case, diffuse reflection by external light may occur in the center of the concave portion 181. For example, when a black image is displayed on the display panel due to diffuse reflection of external light, the black screen is displayed in a redish manner, and black visible characteristics may be deteriorated.

In the light emitting display apparatus 10 according to an embodiment of the present disclosure, the light extraction pattern 180 includes a bottom portion 181a, and the diameter or width W of the bottom portion 181a is set in the range of 59% to 92% of the interval (or pitch) P between the top portions 183a of the convex portion 183, and thus, light extraction efficiency can be increased, and reflection of external light can be reduced. For example, the range of 59% to 92% may be a range with respect to the diameter (or pitch) W of the bottom portion 181a with respect to the interval (or pitch) P of the top portions 183 of the convex portions 183 of the plurality of sub-pixels 12a, 12b, 12c, and 12d. For example, the ranges of each of the plurality of sub-pixels 12a, 12b, 12c, and 12d may be different from each other.

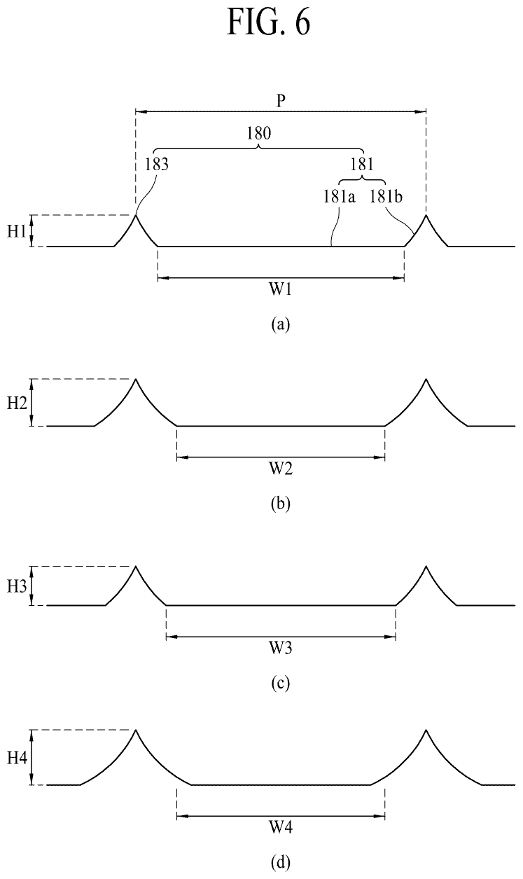

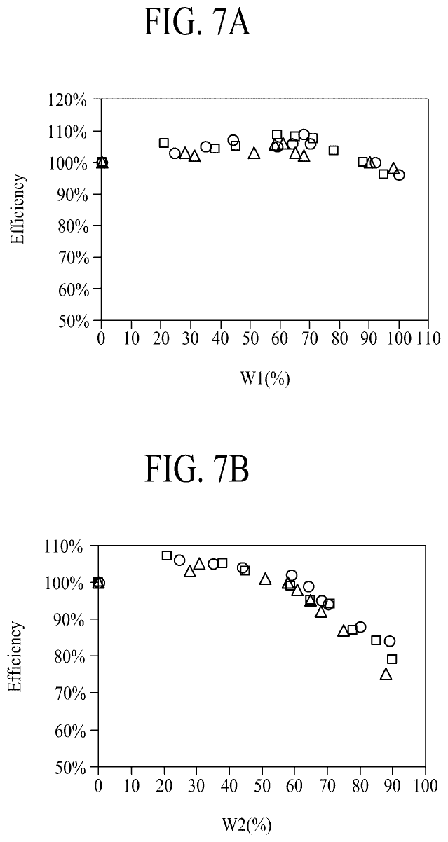

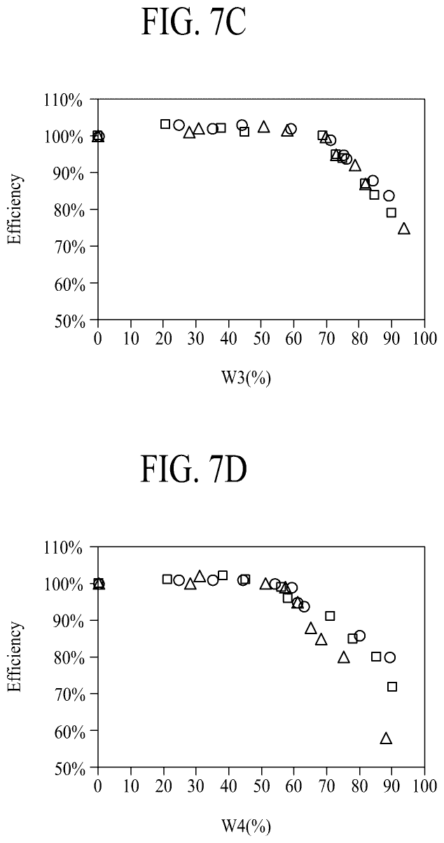

According to an embodiment of the present disclosure, the width W of the bottom portion 181a of the light extraction pattern 180 disposed in each of the plurality of sub-pixels 12a, 12b, 12c, and 12d may be different from each other. For example, the width W of the bottom portion 181a of the light extraction pattern 180 disposed in each of a plurality of sub-pixels 12a, 12b, 12c, and 12d may be set in consideration of luminous efficiency of each of a plurality of sub-pixels 12a, 12b, 12c, and 12d. The width W of the bottom portion 181a of the light extraction pattern 180 disposed in each of a plurality of sub-pixels 12a, 12b, 12c, and 12d may be set within a range in which luminous efficiency of each of a plurality of sub-pixels 12a, 12b, 12c, and 12d is maintained. A configuration of the light extraction pattern 180 with respect to each of a plurality of sub-pixels 12a, 12b, 12c, and 12d will be described in detail with reference to FIGS. 6 and 7A to 7D below.

According to an embodiment of the present disclosure, the light extraction pattern 180 including a plurality of concave portions 181a and convex portion 181b may be formed on the overcoating layer 130 on the opening portion OP through a photolithography process using a photoresist and then formed through an etching process of the overcoating layer 130 using the mask pattern. For example, a positive photoresist may be used as the photoresist to improve productivity. For example, in the photolithography process, an 803T PHT high-resolution exposure machine may be used as the exposure machine. When using a high-resolution exposure machine, it is possible to implement the light extraction pattern 180 having a flat bottom portion 181a between the convex portions 183 by improving the straightness of light.

The light emitting display apparatus 10 according to an embodiment of the present disclosure may further include a light emitting device layer EDL. The light emitting device layer EDL may be disposed on the overcoating layer 150. The light emitting device layer EDL may be disposed on the light extraction pattern 180. The light emitting device layer EDL may be electrically connected to the driving thin film transistor TFT or the pixel circuit PC.

The light emitting device layer EDL may include a first electrode E1, a light emitting device ED, and a second electrode E2.

The first electrode E1 may be disposed on the overcoating layer 150 in a pattern shape. The first electrode E1 may be electrically connected to the source electrode SE of the driving thin film transistor TFT through an electrode contact hole formed in the overcoating layer 150.

The remaining portion except for one end of the first electrode E1 is in direct contact with the light extraction pattern 180, and thus, the first electrode E1 may include a shape which follows the surface shape of the light extraction pattern 180. For example, the first electrode E1 is formed (or deposited) on the overcoating layer 130 to have a relatively thin thickness, and thus, the first electrode E1 may have a surface shape which directly follows the morphology of the light extraction pattern 180. Accordingly, the first electrode E1 may have a surface shape which directly follows the surface shape (or morphology) of the light extraction pattern 180 by a deposition process of a transparent conductive material.

The first electrode E1 may be an anode of the light emitting device ED. The first electrode E1 according to an embodiment may include a transparent conductive material such as a transparent conductive oxide (TCO) so that light emitted from the light emitting device ED may be transmitted toward the substrate 100. For example, the first electrode E1 may be formed of an indium tin oxide (ITO) or an indium zinc oxide (IZO).

The light emitting device ED may be formed on the first electrode E1 to directly contact the first electrode E1. The light emitting device ED according to an embodiment may include any one of an organic light emitting layer, an inorganic light emitting layer, and a quantum dot light emitting layer, or may include a stacked or mixed structure of an organic light emitting layer (or an inorganic light emitting layer) and a quantum dot light emitting layer. The light emitting device ED may include at least one light emitting structure stacked on the first electrode E1 in the order of a hole layer, a light emitting layer, and an electron layer or in the reverse order. For example, the light emitting device ED may be implemented to generate color light corresponding to a corresponding sub-pixel. For example, the light emitting layer of each of the plurality of light emitting structures may generate one or more of blue light, green light, and red light, or a mixed light thereof. For example, the light emitting device ED may be formed (or deposited) on the first electrode E1 to have a relatively thick thickness compared to the first electrode E1.

The second electrode E2 may be formed on the light emitting device ED to be in direct contact with the light emitting device ED. The second electrode E2 according to an embodiment may be formed (or deposited) on the light emitting device ED so as to have a relatively thin thickness compared to the light emitting device ED. Accordingly, the second electrode E2 is formed (or deposited) on the light emitting device ED so as to have a relatively thin thickness, and thus, may have a surface shape that directly follows the surface shape of the light emitting device ED.

The second electrode E2 according to an embodiment may be a cathode of the light emitting device ED. The second electrode E2 according to an embodiment may include a metal material having a high reflectivity to reflect light emitted from the light emitting device ED toward the substrate 100. For example, the second electrode E2 may be formed in a multilayer structure such as a stacked structure (Ti/Al/Ti) of aluminum (Al) and titanium (Ti), a stacked structure (ITO/Al/ITO) of aluminum (Al) and indium tin oxide, an APC (Ag/Pd/Cu) alloy, and a stacked structure (ITO/APC/ITO) of an APC alloy and ITO. For example, the second electrode E2 may include a single layer structure made of any one material selected from silver (Ag), aluminum (Al), molybdenum (Mo), gold (Au), magnesium (Mg), calcium (Ca), or barium (Ba).

The light emitting display apparatus 10 according to an embodiment of the present disclosure may further include a bank 160.

The bank 160 may define an opening (or light emitting area) of the sub-pixel SP and may be disposed to cover an edge portion of the first electrode E1. For example, the bank 160 may be disposed on the overcoating layer 150 to cover only an edge portion excluding a central portion of the first electrode E1. For example, the bank 160 may be formed of an organic material or an inorganic material, and may include a light absorbing material including a black pigment.

The light emitting device ED may be disposed only in the opening portion OP of each of the sub-pixels 12a, 12b, 12c, and 12d provided by the bank 160 or on the opening portion OP of each of the sub-pixels 12a, 12b, 12c, and 12d and the bank 160.

The encapsulating portion 170 may be disposed on the light emitting device layer EDL and may cover or surround the light emitting device layer EDL.

The encapsulating portion (or encapsulating layer) 170 may include one or more encapsulating portion. For example, the encapsulating portion 170 may include at least one inorganic layer on the light emitting device layer EDL. In addition, the encapsulating portion 170 may further include at least one organic layer on the light emitting device layer EDL. For example, the encapsulating portion 170 may include a first inorganic encapsulating layer, an organic encapsulating layer, and a second inorganic encapsulating layer. The first and second inorganic encapsulating layers may include any one inorganic material among a silicon oxide layer (SiOx), a silicon nitride layer (SiNx), a silicon oxynitride layer (SiON), a titanium oxide layer (TiOx), and an aluminum oxide layer (AlOx). In addition, the organic encapsulating layer may be formed of any one of an acrylic resin, an epoxy resin, a phenolic resin, a phenolic resin, a polyamide resin, a polyimide resin, and a benzocyclobutene resin. The organic encapsulating layer may be represented by a foreign material cover layer.

For example, the encapsulating portion 170 may be changed to a filler surrounding the entire pixel. In this case, the light emitting display apparatus 10 according to the present disclosure may further include an opposite substrate 200 attached onto the substrate 100 via a filler. The opposite substrate 200 may be formed of a plastic material, a glass material, or a metal material. The filler may include a getter material that absorbs oxygen or/and moisture.

FIG. 6 is a cross-sectional view illustrating a cross-sectional structure of a light extraction pattern in each pixel area according to an embodiment of the present disclosure. FIG. 6 illustrates a light extraction pattern of each sub-pixel in the light emitting display apparatus according to an embodiment of the present disclosure described with reference to FIGS. 1 to 5. In FIG. 6, FIG. 6A illustrates a light extraction pattern disposed in the first sub-pixel (or red sub-pixel), and FIG. 6B illustrates a light extraction pattern disposed in the second sub-pixel (or white sub-pixel). In FIG. 6, FIG. 6C illustrates a light extraction pattern disposed in the third sub-pixel (or green sub-pixel), and FIG. 6D illustrates a light extraction pattern disposed in the fourth sub-pixel (or blue sub-pixel).

Referring to FIG. 6, the light extraction pattern 180 according to an embodiment of the present disclosure may be configured in each of a plurality of pixel regions 12a, 12b, 12c, and 12d. A plurality of pixel regions 12a, 12b, 12c, and 12d may include first to fourth sub-pixels 12a, 12b, 12c, and 12d parallel to each other in the first direction X. The first sub-pixel 12a may be a red sub-pixel, the second sub-pixel 12b may be a white sub-pixel, the third sub-pixel 12c may be a green sub-pixel, and the fourth sub-pixel 12d may be a blue sub-pixel.

The light extraction pattern 180 configured in each of a plurality of pixel regions 12a, 12b, 12c, and 12d may include a plurality of concave portions 181 and a convex portion 183. Each of a plurality of concave portions 181 may include a bottom portion 181a and an inclined portion 181b.

The distance (or pitch) between the top portions 183a of the convex portion 183 may be set to be the same for each sub-pixel 12a, 12b, 12c, and 12d within a process error range. Widths of the bottom portion 181a of the light extraction pattern 180 disposed in each of at least two or more sub-pixels 12a, 12b, 12c, and 12d may be different from each other.

Height of the inclined portion 181b of the light extraction pattern 180 disposed in each of a plurality of sub-pixels 12a, 12b, 12c, and 12d may be different from each other. For example, the height from the top surface of the bottom portion 181a of the light extraction pattern 180 disposed in each of a plurality of sub-pixel regions 12a, 12b, 12c, and 12d to the top surface of the convex portion 183 may be equal to or less than 16% of the distance or pitch between the adjacent convex portions 183. For example, the height from the top surface of the bottom portion 181a of the light extraction pattern 180 disposed in each of a plurality of sub-pixel regions 12a, 12b, 12c, and 12d to the top surface of the convex portion 183 may range from 13% to 16% of the distance or pitch between the adjacent convex portions 183. For example, when the height from the upper surface of the bottom portion 181a of the light extraction pattern 180 to the upper surface of the convex portion 183 exceeds 16% of the distance or pitch between adjacent convex portions 183, the light extraction efficiency of the display panel may decrease.

Accordingly, the height from the top surface of the bottom portion 181a of the light extraction pattern 180 disposed in each of a plurality of sub-pixel regions 12a, 12b, 12c, and 12d to the top surface of the convex portion 183 may be set in the range of 13% to 16% of the distance or pitch between the adjacent convex portions 183. For example, the height H1 of the inclined portion 181b of the light extraction pattern 180 disposed in the first sub-pixel 12a may be equal to or less than 16% of the distance or pitch P between the adjacent convex portions 183. For example, the heights H2 and H3 of the inclined portions 180b disposed in the second and third sub-pixels 12b and 12c may be in the range of 13% to 16% of the distance or pitch P between the adjacent convex portions 183. For example, the height H4 of the inclined portion 181b of the light extraction pattern 180 disposed in the fourth sub-pixel 14d may range from 14% to 16% of the pitch P or the distance between the adjacent convex portions 183.

According to an embodiment of the present disclosure, the width W1 of the bottom portion 181a of the light extraction pattern 180 disposed in the first sub-pixel 12a or the red sub-pixel may be greater than the widths W2, W3, and W4 of the bottom portion 181a disposed in the second to fourth sub-pixels 12b, 12c, and 12d. The width W1 of the bottom portion 181a of the light extraction pattern 180 disposed in the first sub-pixel 12a or the red sub-pixel may be greater than the widths W2, W3, and W4 of the bottom portion 181a disposed in each of the white sub-pixel, the green sub-pixel, and the blue sub-pixel.

For example, the width W1 of the bottom portion 181a of the light extraction pattern 180 disposed in the first sub-pixel 12a or the red sub-pixel may range from 88% to 92% of the distance or pitch P between adjacent convex portions 183. For example, when the width W1 of the bottom portion 181a of the light extraction pattern 180 disposed in the first sub-pixel 12a or the red sub-pixel is formed to be less than 88% or more than 92% of the pitch P between the adjacent convex portions 183, the light extraction efficiency of the red sub-pixel region may be deteriorated. Accordingly, the width W1 of the bottom portion 181a of the light extraction pattern 180 disposed in the first sub-pixel 12a or the red sub-pixel may be set in the range of 88% to 92% of the distance or pitch P between adjacent convex portions 183 in consideration of light extraction efficiency and diffuse reflection of external light.

For example, the width W1 of the bottom portion 181a of the light extraction pattern 180 disposed in the first sub-pixel 12a or the red sub-pixel is greater than the widths W2, W3, and W4 of the bottom portion 181a disposed in the second to fourth sub-pixels 12b, 12c, and 12d, and thus, the height H1 of the inclined portion 181b of the light extraction pattern 180 disposed in the first sub-pixel 12a or the red sub-pixel may be less than the heights H2, H3, and H4 of the inclined portion 181b disposed in the second to fourth sub-pixels 12b, 12c, and 12d.

According to an embodiment of the present disclosure, the width W2 of the bottom portion 181a of the light extraction pattern 180 disposed in the second sub-pixel 12b or the white sub-pixel may be smaller than the widths W1 and W3 of the bottom portion 181a disposed in the first and third sub-pixels 12a and 12c and may be equal to or greater than the fourth sub-pixel 12d. The width W2 of the bottom portion 181a of the light extraction pattern 180 disposed in the second sub-pixel 12b or the white sub-pixel may be smaller than the widths W1 and W3 of the bottom portion 181a disposed in each of the red sub-pixels and the green sub-pixels. The width W2 of the bottom portion 181a of the light extraction pattern 180 disposed in the second sub-pixel 12b or the white sub-pixel may be equal to or greater than the width W4 of the bottom portion 181a disposed in the blue sub-pixel.

For example, the width W2 of the bottom portion 181a of the light extraction pattern 180 disposed in the second sub-pixel 12b or the white sub-pixel may range from 59% to 64% of the distance or pitch P between the adjacent convex portions 183. For example, when the width W2 of the bottom portion 181a of the light extraction pattern 180 disposed in the second sub-pixel 12b or the white sub-pixel is formed to be less than 59% or more than 64% of the pitch P between the adjacent convex portions 183, the light extraction efficiency of the red sub-pixel region may be deteriorated. Accordingly, the width W2 of the bottom portion 181a of the light extraction pattern 180 disposed in the second sub-pixel 12b or the white sub-pixel may be set in the range of 59% to 64% of the distance or pitch P between adjacent convex portions 183 in consideration of light extraction efficiency and diffuse reflection of external light.

For example, the width W2 of the bottom portion 181a of the light extraction pattern 180 disposed in the second sub-pixel 12b or the white sub-pixel is smaller than the widths W1 and W3 of the bottom portion 181a disposed in the first and third sub-pixels 12a and 12c, and thus, the height H2 of the inclined portion 181b of the light extraction pattern 180 disposed in the second sub-pixel 12b or the white sub-pixel may be greater than the heights H1 and H3 of the inclined portions 181b disposed in the first and third sub-pixels 12a and 12c. For example, the width W2 of the bottom portion 181a of the light extraction pattern 180 disposed in the second sub-pixel 12b or the white sub-pixel is equal to or greater than the width W4 of the bottom portion 181a disposed in the fourth sub-pixel 12d, and thus, the height H2 of the inclined portion 181b of the light extraction pattern 180 disposed in the second sub-pixel 12b or the white sub-pixel may be equal to or less than the height H4 of the inclined portion 181b disposed in the fourth sub-pixel 12d.

According to an embodiment of the present disclosure, the width W3 of the bottom portion 181a of the light extraction pattern 180 disposed in the third sub-pixel 12c or the green sub-pixel may be smaller than the width W1 of the bottom portion 181a disposed in the first sub-pixel 12a and may be greater than the widths W2 and W4 of the bottom portion 181a disposed in the second and fourth sub-pixels 12b and 12d. The width W3 of the bottom portion 181a of the light extraction pattern 180 disposed in the third sub-pixel 12c or the green sub-pixel may be smaller than the width W1 of the bottom portion 181a disposed in the red sub-pixel. The width W3 of the bottom portion 181a of the light extraction pattern 180 disposed in the third sub-pixel 12c or the green sub-pixel may be greater than the widths W2 and W4 of the bottom portion 181a disposed in each of the white sub-pixel and the blue sub-pixel.

For example, the width W3 of the bottom portion 181a of the light extraction pattern 180 disposed in the third sub-pixel 12c or the green sub-pixel may be in the range of 69% to 71% of the distance or pitch P between the adjacent convex portions 183. For example, when the width W3 of the bottom portion 181a of the light extraction pattern 180 disposed in the third sub-pixel 12c or the green sub-pixel is formed to be less than 69% or more than 71% of the pitch P between the adjacent convex portions 183, the light extraction efficiency of the green sub-pixel region may be deteriorated. Accordingly, the width W3 of the bottom portion 181a of the light extraction pattern 180 disposed in the third sub-pixel 12c or the green sub-pixel may be set in the range of 67% to 71% of the distance or pitch P between the adjacent convex portions 183 in consideration of light extraction efficiency and diffuse reflection of the external light.

For example, the width W3 of the bottom portion 181a of the light extraction pattern 180 disposed in the third sub-pixel 12c or the green sub-pixel is smaller than the width W1 of the bottom portion 181a disposed in the first sub-pixel 12a, and thus, the height H3 of the inclined portion 181b of the light extraction pattern 180 disposed in the third sub-pixel 12c or the green sub-pixel may be greater than the height H1 of the inclined portion 181b disposed in the first sub-pixel 12a. For example, the width W3 of the bottom portion 181a of the light extraction pattern 180 disposed in the third sub-pixel 12c or the green sub-pixel is greater than the width W2 and W4 of the bottom portion 181a disposed in the second and fourth sub-pixels 12b and 12d, and thus, the height H3 of the inclined portion 181b of the light extraction pattern 180 disposed in the third sub-pixel 12c or the green sub-pixel may be less than the heights H2 and H4 of the inclined portion 181b disposed in the second and fourth sub-pixels 12b and 12d.

According to an embodiment of the present disclosure, the width W4 of the bottom portion 181a of the light extraction pattern 180 disposed in the fourth sub-pixel 12d or the blue sub-pixel may be smaller than the widths W1 and W3 of the bottom portion 181a disposed in the first and third sub-pixel 12a and 12c and may be equal to or less than the second sub-pixel 12b. The width W4 of the bottom portion 181a of the light extraction pattern 180 disposed in the fourth sub-pixel 12d or the blue sub-pixel may be smaller than the widths W1 and W3 of the bottom portion 181a disposed in the red sub-pixel and the green sub-pixel, respectively. The width W4 of the bottom portion 181a of the light extraction pattern 180 disposed in the fourth sub-pixel 12b or the blue sub-pixel may be equal to or smaller than the width W2 of the bottom portion 181a disposed in the white sub-pixel.

For example, the width W4 of the bottom portion 181a of the light extraction pattern 180 disposed in the fourth sub-pixel 12d or the blue sub-pixel may range from 56% to 59% of the distance or pitch P between the adjacent convex portions 183. For example, when the width W4 of the bottom portion 181a of the light extraction pattern 180 disposed in the fourth sub-pixel 12d or the blue sub-pixel is formed to be less than 56% or more than 59% of the pitch P between the adjacent convex portions 183, the light extraction efficiency of the blue sub-pixel region may be deteriorated. Accordingly, the width W4 of the bottom portion 181a of the light extraction pattern 180 disposed in the fourth sub-pixel 12d or the blue sub-pixel may be set in the range of 56% to 59% of the distance or pitch P between adjacent convex portions in consideration of light extraction efficiency and diffuse reflection of external light.

For example, the width W4 of the bottom portion 181a of the light extraction pattern 180 disposed in the fourth sub-pixel 12d or the blue sub-pixel is smaller than the widths W1 and W3 of the bottom portion 181a disposed in the first and third sub-pixels 12a and 12c, and thus, the height H4 of the inclined portion 181b of the light extraction pattern 180 disposed in the fourth sub-pixel 12d or the blue sub-pixel may be greater than the heights H1 and H3 of the inclined portion 181b disposed in the first and third sub-pixels 12a and 12c. For example, the width W4 of the bottom portion 181a of the light extraction pattern 180 disposed in the fourth sub-pixel 12d or the blue sub-pixel is equal to or smaller than the width W2 of the bottom portion 181a disposed in the second sub-pixel 12b, and thus, the height H4 of the inclined portion 181b of the light extraction pattern 180 disposed in the fourth sub-pixel 12d or the blue sub-pixel may be equal to or greater than the height H2 of the inclined portion 181b disposed in the second sub-pixel 12b.

In the light emitting display apparatus 10 according to an embodiment of the present disclosure, the light extraction pattern 180 includes a bottom portion 181a, and the width of the bottom portion 181a of the light extraction pattern 180 disposed in each of at least two or more sub-pixels 12a, 12b, 12c, and 12d is different from each other, and thus, light extraction efficiency can be increased, and reflection of external light can be reduced at a same time.

In the light emitting display apparatus according to an embodiment of the present disclosure, a visual perception of black images may be enhanced due to the reduction in external light reflection.

In addition, the light emitting display apparatus according to an embodiment of the present disclosure may be improved the light extraction efficiency and a visual perception of black images, and thus, there is an effect of reducing power consumption and driving low power according to the improvement of a lifetime.

FIGS. 7A to 7D are diagrams illustrating light extraction efficiency of a light emitting display apparatus according to a width of a bottom portion according to an embodiment of the present disclosure. FIGS. 7A to 7D illustrate the light extraction efficiency of the light emitting display apparatus according to the width of the bottom portion of each sub-pixels in the light emitting display apparatus according to the embodiment of the present disclosure described above with reference to FIGS. 1 to 5.

FIG. 7A illustrates the light extraction efficiency according to a width of the bottom portion of the light extraction pattern disposed in a first sub-pixel (or a red sub-pixel), and FIG. 7B illustrates the light extraction efficiency according to a width of the bottom portion of the light extraction pattern disposed in a second sub-pixel (or a white sub-pixel). FIG. 7C illustrates the light extraction efficiency according to a width of the bottom portion of the light extraction pattern disposed in a third sub-pixel (or a green sub-pixel), and FIG. 7D illustrates the light extraction efficiency according to a width of the bottom portion of the light extraction pattern disposed in a fourth sub-pixel (or a blue sub-pixel). In FIGS. 7A to 7D, the abscissa axis illustrates widths W1, W2, W3, and W4 of the bottom portion according to a pitch, and the ordinate axis illustrates the light extraction efficiency. In FIGS. 7A to 7D, a square, a circle, and a triangle represent embodiments 1 to 3, respectively.

In each of the embodiments 1 to 3, the light extraction pattern is formed by adjusting a hole of a mask and a gap between the holes in order to realize a concave portion and a convex portion in the process of forming the light extraction pattern. For example, light is irradiated through a hole (or an open portion) of the mask, and a portion irradiated with light is etched to form the concave portion having a bottom portion and an inclined portion. For example, the bottom portion is a portion where light is irradiated vertically and has a fast etching speed, and the inclined portion is a portion where light is irradiated obliquely toward an end of the hole and has a slow etching speed. By controlling the amount of light irradiated through the mask and the etching speed, the light extraction pattern having the bottom portion and the inclined portion may be realized. In the embodiments 1 to 3, a size of the hole was a same as 1.5 μm, and a shape of the light extraction pattern was controlled by adjusting a size of the gap. In FIGS. 7A to 7D, the sizes of the gaps of the squares, circles, and triangles are 1.7 μm, 2.1 μm, and 2.4 μm, respectively, and the larger the size of the gap, the greater a distance between the adjacent concave portions.

Referring to FIG. 7A, in the case of the light extraction pattern disposed in the first sub-pixel (or red sub-pixel), when the width W1 of the bottom portion of the light extraction pattern disposed in the first sub-pixel (or red sub-pixel) is formed to be less than 88% or greater than 92% of a distance or a pitch between adjacent convex portions. Therefore, it was confirmed that the width W1 of the bottom portion of the light extraction pattern disposed in the first sub-pixel or red sub-pixel may be set in a range of 88% to 92% of the distance or the pitch between adjacent convex portions in consideration of the light extraction efficiency and diffuse reflection of an external light.

Referring to FIG. 7B, when the width (W2) of the bottom portion of the light extraction pattern disposed in the second sub-pixel (or white sub-pixel) is formed to be less than 59% or greater than 64% of the distance or the pitch between adjacent convex portions, the light extraction efficiency of the white sub-pixel area has deteriorated. Therefore, it was confirmed that the width (W2) of the bottom portion of the light extraction pattern disposed in the second sub-pixel or white sub-pixel may be set in a range of 59% to 64% of the distance or the pitch between adjacent convex portions in consideration of the light extraction efficiency and diffuse reflection of an external light.

Referring to FIG. 7C, when the width W3 of the bottom portion of the light extraction pattern disposed in the third sub-pixel (or green sub-pixel) is formed to be less than 69% or greater than 71% of the distance or the pitch between adjacent convex portions, the light extraction efficiency of the green sub-pixel area has deteriorated. Therefore, it was confirmed that the width W3 of the bottom portion of the light extraction pattern disposed in the third sub-pixel or the green sub-pixel may be set in a range of 67% to 71% of the distance or the pitch between adjacent convex portions in consideration of the light extraction efficiency and diffuse reflection of an external light.

Referring to FIG. 7D, when the width W4 of the bottom portion of the light extraction pattern disposed in the fourth sub-pixel (or blue sub-pixel) is formed to be less than 56% or greater than 59% of the distance or the pitch between adjacent convex portions, the light extraction efficiency of the blue sub-pixel area has deteriorated. Therefore, it was confirmed that the width W4 of the bottom portion of the light extraction pattern disposed in the fourth sub-pixel or blue sub-pixel could be set in a range of 56% to 59% of the distance or the pitch between adjacent convex portions in consideration of the light extraction efficiency and diffuse reflection of an external light.

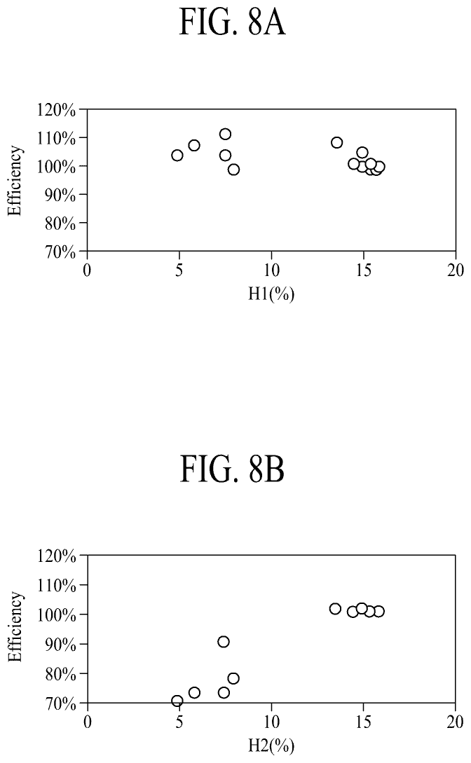

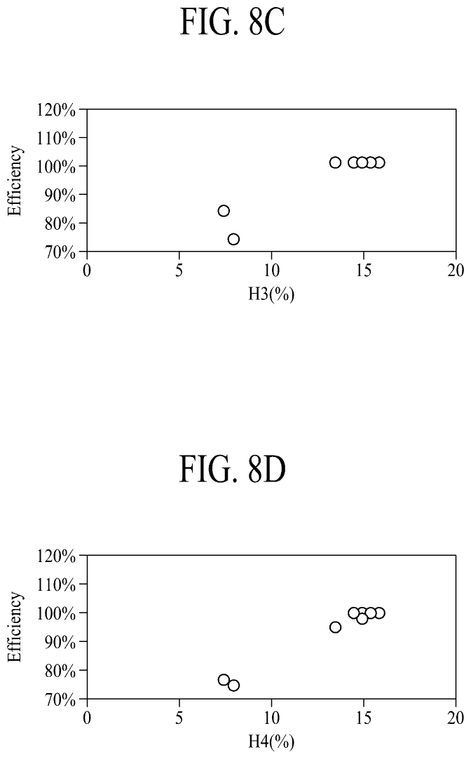

FIGS. 8A to 8D are diagrams illustrating light extraction efficiency of a light emitting display apparatus according to a height of a light extraction pattern according to an embodiment of the present disclosure. Each of FIGS. 8A to 8D illustrates the light extraction efficiency according to a height of an inclined portion of a light extraction pattern disposed in each of a first sub-pixel (or red sub-pixel), a second sub-pixel (or white sub-pixel), a third sub-pixel (or green sub-pixel), and a fourth sub-pixel (or blue sub-pixel). In FIGS. 8A to 8D, the abscissa axis illustrates a height of the inclined portion according to a pitch, and the ordinate axis illustrates the light extraction efficiency.

Referring to FIGS. 8A to 8D, it was confirmed that when a height H1 of the inclined portion according to the pitch is 16% or less, all of the first sub-pixels exhibit the light extraction efficiency of 100% or more. In the second and third sub-pixels, it was confirmed that when heights H2 and H3 of the inclined portion according to the pitch are less than 13%, the light extraction efficiency has deteriorated. In the fourth sub-pixel, it was confirmed that when a height H4 of the inclined portion according to the pitch is less than 14%, the light extraction efficiency has deteriorated. It was confirmed that when the height of the inclined portion according to the pitch exceeds 16% in all of the first to fourth sub-pixels, the light extraction efficiency of the first to fourth sub-pixels. It was confirmed that similar light extraction efficiency was exhibited when all of the first to fourth sub-pixels exceeded 16%.

Therefore, considering the light extraction efficiency of each of the plurality of sub-pixel areas, the height of the inclined portion of the light extraction pattern disposed in the first sub-pixel is less than 16% of the distance or the pitch between the adjacent convex portions, and the height of the inclined portion of the light extraction pattern disposed in the second and third sub-pixels is set in the range of 13% to 16% of the distance or the pitch between the adjacent convex portions. In addition, the height of the inclined portion of the light extraction pattern disposed in the fourth sub-pixel is set in the range of 14% to 16% of the distance or the pitch between the adjacent convex portions.

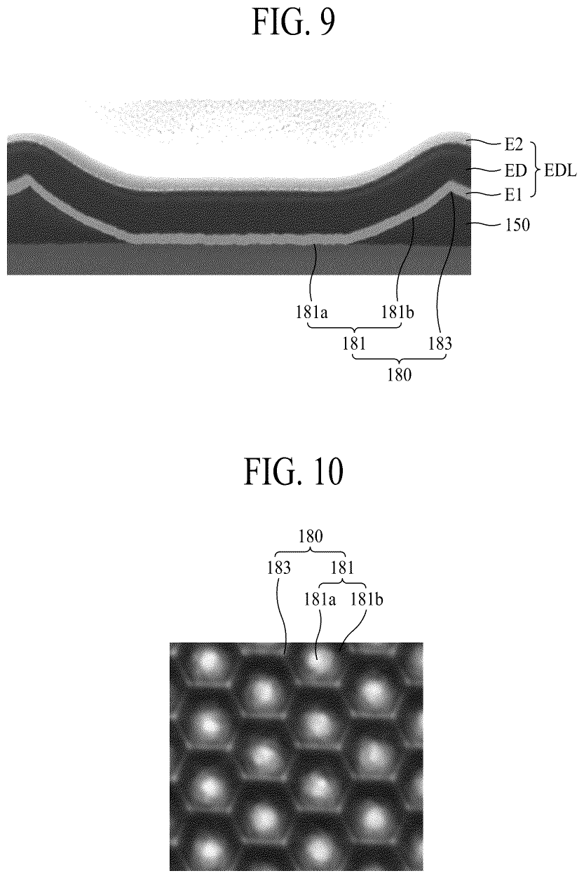

FIG. 9 is a diagram illustrating an image of a light extraction pattern according to an embodiment of the present disclosure. FIG. 10 is a diagram illustrating a 3D image of a light extraction pattern according to an embodiment of the present disclosure. FIG. 9 illustrates a cross-sectional view of the light extraction pattern using a FIB (Focused Ion Beam) image, and schematically illustrates an overcoating layer on a substrate and patterning the overcoating layer by controlling the exposure amount, in order to determine whether it is possible to implement the light extraction pattern including a bottom portion. FIG. 10 is a view of the light extraction pattern observed using a 3D microscopic.

Referring to FIGS. 9 and 10, it was confirmed that the light extraction pattern according to an embodiment of the present disclosure may be formed by adjusting the exposure amount of the mask, and a flat bottom portion and a concave portion having the inclined portion around the bottom portion may be realized.

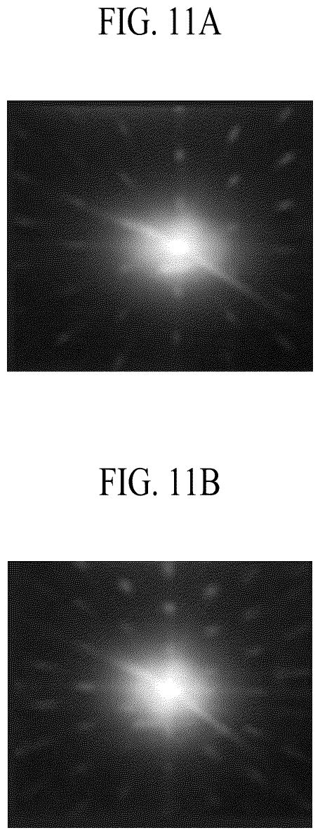

FIGS. 11A and 11B are diagrams illustrating the visual quality of a black image according to an experimental example and an embodiment of the present disclosure.

In order to evaluate the visual perception of black images according to an embodiment of the present disclosure, the inventors of the present disclosure prepared samples according to an experimental example and the embodiment 4. The experimental example relates to a light emitting display apparatus including a hemispherical light extraction pattern, and the embodiment 4 relates to the light emitting display apparatus described above with reference to FIGS. 1 to 6. FIG. 11A illustrates a visual perception of black images according to the experimental example, and FIG. 11B illustrates a visual perception of black images according to the embodiment 4. The visual perception of black images was captured using a camera on an actual use screen.

Referring to FIGS. 11A and 11B, as compared with the experimental example, in the embodiment 4, it was confirmed that a reddish portion generated according to reflection of external light was reduced when a black image was implemented. For example, at a wavelength of 550 nm, the experimental example illustrated a color coordinate of 2.25/0.95 and the embodiment 4 illustrated a color coordinate of 0.9/1.0. Accordingly, it was confirmed that the visual perception of black images of an entire display panel may be improved in the embodiment 4.

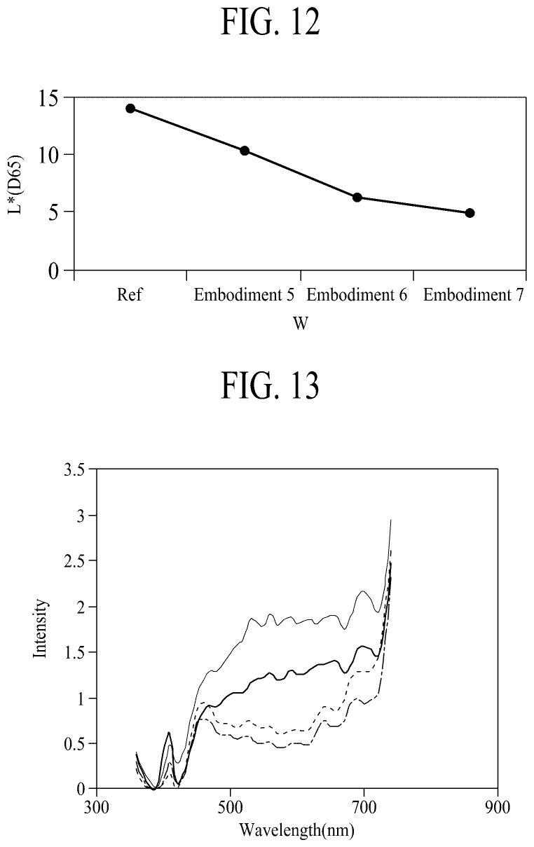

FIG. 12 is a diagram illustrating diffuse reflection according to the width of the bottom portion of the light extraction pattern according to an embodiment of the present disclosure.

In order to evaluate the diffuse reflectance according to the size of the bottom portion according to an embodiment of the present disclosure, the inventors of the present disclosure prepared samples according to an experimental example and the embodiments 5 to 7.

The experimental example relates to a light emitting display apparatus including a hemispherical light extraction pattern, and the embodiments 5 to 7 are the light emitting display apparatus described above with reference to FIGS. 1 to 6, in which the width of the bottom portion is set to 2.54, 2.62, and 3.84, respectively. This is 51%, 52%, and 77% of the size of the pitch, respectively.

FIG. 12 is to find out the tendency that the degree of diffuse reflection of light extraction patterns different from the width of the bottom portion varies, and as an example, it measures a white pixel area. The measurement was performed with a surface reflectance meter, the measurement principle is to measure the intensity of light reflected from the surface of the medium after incident light is incident on the medium, thereby indicating the ratio of the energy of the reflected wave to the energy of the incident wave. A Y-axis is the L value when the reflected light is expressed in the L*a*b* coordinate system, and as a numerical value representing brightness, 0 means a black and 100 means a white.

Referring to FIG. 12, the diffuse reflectance of the experimental example was measured as 14, and the diffuse reflectance of each of the embodiments 5 to 7 was measured as 10.3, 6.22, and 4.87. As the measurement value approaches 0, it is closer to black, and it was confirmed that the diffuse reflectance of the light-emitting display device tends to decrease as the width of the bottom increases. According to an embodiment of the present disclosure, the width of the bottom portion of each pixel area may be set in consideration of the diffuse reflectance and the light extraction efficiency of FIGS. 7A and 7B.

FIG. 13 is a diagram illustrating the intensity of light according to the wavelength range in the experimental example and the embodiment of the present disclosure.

In order to evaluate the intensity of light according to the size of the bottom portion according to an embodiment of the present disclosure, the inventors of the present disclosure prepared samples in the experimental example and the embodiments 8 to 10. The experimental example relates to a light emitting display apparatus including a hemispherical light extraction pattern, and the embodiments 8 to 10 are the light emitting display apparatus described above with reference to FIGS. 1 to 6, in which the width of the bottom portion is set to 2.54, 2.62, and 3.84, respectively. This is 51%, 52%, and 77% of the size of the pitch, respectively. FIG. 13 is to find out the tendency that the degree of diffuse reflection of light extraction patterns different from the width of the bottom portion varies, and as an example, it measures a white pixel area. In FIG. 13, each of a solid line, a thick solid line, a dotted line, and an alternate long and short dash line is a measured value for the experimental example and the embodiments 8 to 10. FIG. 13 is a result of measurement using a surface reflectance meter, is the result of measuring the ratio of the energy of the reflected wave to the energy of the incident wave, and the graph shows the intensity of each wavelength of the reflected light.

Referring to FIG. 13, in the range of 500 nm to 700 nm, it was confirmed that the intensity of light is reduced in the embodiments 8 to 10 compared with the experimental example. Accordingly, as the width of the bottom portion was increased, it was confirmed that the intensity of the reflected light of the light emitting display apparatus was reduced. Therefore, as the width of the bottom portion was increased, it was confirmed that the diffuse reflection of the light emitting display apparatus was reduced.

The above-described feature, structure, and effect of the present disclosure are included in at least one embodiment of the present disclosure, but are not limited to only one embodiment. Furthermore, the feature, structure, and effect described in at least one embodiment of the present disclosure can be implemented through combination or modification of other embodiments by those skilled in the art. Therefore, content associated with the combination and modification should be construed as being within the scope of the present disclosure.

It will be apparent to those skilled in the art that various modifications and variations can be made in the present disclosure without departing from the spirit or scope of the disclosure. Thus, it is intended that the present disclosure covers the modifications and variations of this disclosure provided they come within the scope of the present disclosure. The scope of protection of the present disclosure should be construed based on the following claims, and all technical features within the scope of equivalents thereof should be construed as being included within the scope of the present disclosure.

What is claimed is:

1. A light emitting display apparatus, comprising:
a substrate;
a plurality of sub-pixels;
a light extraction pattern disposed in each of the plurality of sub-pixels; and
a light emitting device layer disposed on the light extraction pattern,
wherein the light extraction pattern includes a plurality of concave portions and a convex portion around the plurality of concave portions,
wherein each of the plurality of concave portions includes a bottom portion and an inclined portion surrounding the bottom portion, and
wherein a width of the bottom portion of the light extraction pattern disposed in at least two or more sub-pixels among the plurality of sub-pixels are different from each other.

2. The light emitting display apparatus of claim 1, wherein in each of the plurality of concave portions, the width of the bottom portion is smaller than a distance or a pitch between adjacent convex portions.

3. The light emitting display apparatus of claim 1, wherein:
the plurality of sub-pixels include first to fourth sub-pixels parallel to each other in a first direction, and
the first sub-pixel is a red sub-pixel, the second sub-pixel is a white sub-pixel, the third sub-pixel is a green sub-pixel, and the fourth sub-pixel is a blue sub-pixel.

4. The light emitting display apparatus of claim 3, wherein the width of the bottom portion of the light extraction pattern disposed in the red sub-pixel is greater than the width of the bottom portion of the light extraction pattern disposed in each of the white sub-pixel, the green sub-pixel, and the blue sub-pixel.

5. The light emitting display apparatus of claim 3, wherein the width of the bottom portion of the light extraction pattern disposed in the green sub-pixel is greater than the width of the bottom portion of the light extraction pattern disposed in each of the white sub-pixel and the blue sub-pixel.

6. The light emitting display apparatus of claim 3, wherein the width of the bottom portion of the light extraction pattern disposed in the white sub-pixel is equal to or greater than the width of the bottom portion of the light extraction pattern disposed in the blue sub-pixel.

7. The light emitting display apparatus of claim 3, wherein the width of the bottom portion of the light extraction pattern disposed in the red sub-pixel is in a range of 88% to 92% of a distance between adjacent convex portions.

8. The light emitting display apparatus of claim 3, wherein the width of the bottom portion of the light extraction pattern disposed in the white sub-pixel is in a range of 59% to 64% of a distance between adjacent convex portions.

9. The light emitting display apparatus of claim 3, wherein the width of the bottom portion of the light extraction pattern disposed in the green sub-pixel is in a range of 69% to 71% of a distance between adjacent convex portions.

10. The light emitting display apparatus of claim 3, wherein the width of the bottom portion of the light extraction pattern disposed in the blue sub-pixel is in a range of 56% to 59% of a distance between adjacent convex portions.

11. The light emitting display apparatus of claim 1, wherein the inclined portion is inclined at a first angle from an upper surface of the bottom portion.

12. The light emitting display apparatus of claim 11, wherein the first angle is in a range of 21° to 40°.

13. The light emitting display apparatus of claim 3, wherein a height of the inclined portion of the light extraction pattern disposed in at least two or more sub-pixels among the plurality of sub-pixels are different from each other.

14. The light emitting display apparatus of claim 3, wherein:
a height of the inclined portion of the light extraction pattern disposed in the first sub-pixel is in a range of 16% or less of a distance or a pitch between adjacent convex portions,
a height of the inclined portion of the light extraction pattern disposed in each of the second and third sub-pixels is in a range of 13% to 16% of a distance or a pitch between adjacent convex portions, and
a height of the inclined portion of the light extraction pattern disposed in the fourth sub-pixel is in a range of 14% to 16% of a distance or a pitch between adjacent convex portions.

15. The light emitting display apparatus of claim 3, wherein a height of the inclined portion of the light extraction pattern disposed in the red sub-pixel is smaller than a height of the inclined portion of the light extraction pattern disposed in each of the white sub-pixel, the green sub-pixel, and the blue sub-pixel.

16. The light emitting display apparatus of claim 3, wherein a height of the inclined portion of the light extraction pattern disposed in the green sub-pixel is smaller than a height of the inclined portion of the light extraction pattern disposed in each of the white sub-pixel and the blue sub-pixel.

17. The light emitting display apparatus of claim 3, wherein a height of the inclined portion of the light extraction pattern disposed in the white sub-pixel is equal to or smaller than a height of the inclined portion of the light extraction pattern disposed in the blue sub-pixel.

18. The light emitting display apparatus of claim 1, further comprising:
a wavelength conversion layer disposed at each of the plurality of sub-pixels; and
an overcoating layer disposed on the wavelength conversion layer,
wherein the light extraction pattern is formed at the overcoating layer.

19. The light emitting display apparatus of claim 18, wherein the bottom portion of the light extraction pattern and the wavelength conversion layer are spaced apart from each other.
